(19) United States
(12) Patent Application Publication
(10) Pub. No.: US 2012/0071076 A1
(43) Pub. Date: Mar. 22, 2012

(54) CONTAINER DATA CENTER AND HEAT DISSIPATION SYSTEM

(75) Inventors: CHAO-KE WEI, Tu-Cheng (TW); HUNG-CHOU CHAN, Tu-Cheng (TW)

(73) Assignee: HON HAI PRECISION INDUSTRY CO., LTD., Tu-Cheng (TW)

(21) Appl. No.: 12/894,171

(22) Filed: Sep. 30, 2010

(30) Foreign Application Priority Data
Sep. 20, 2010 (TW) 99131849

(51) Int. Cl. H05K 5/02; F24F 7/007

(52) U.S. Cl. 454/184; 454/343

(57) ABSTRACT

A container data center includes a container, a number of server systems, and a number of fan apparatuses. Each fan apparatus includes a number of guides to guide airflow of the cooling airflow, a guide driver to drive the guides, and a micro control unit (MCU) to control the guide driver. Each server system includes a temperature sensor to determine temperature of the server system. The MCU of each fan apparatus is connected to two temperature sensors of two server systems nearest to the fan apparatus but not in the same row. The MCU receives two temperature signals from two corresponding temperature sensors and directs the guide driver to rotate the guides towards the server system with higher temperature.

### BACKGROUND

1. Technical Field

The present disclosure relates to device cooling, and particularly to a container data center and a heat dissipation system of the container data center.

2. Description of Related Art

With increasing heavy use of online applications, the need for computer data centers has increased rapidly. Data centers are centralized computing facilities that include many servers, often arranged on server racks or shelves, with one rack or shelf with some servers considered a server system. In a working state, the server systems generate heat in the data centers, therefore effective heat dissipation is necessary.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a partial, schematic view of an embodiment of a data center, the data center including a heat dissipation system.

FIG. 2 is a block diagram of the heat dissipation system of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

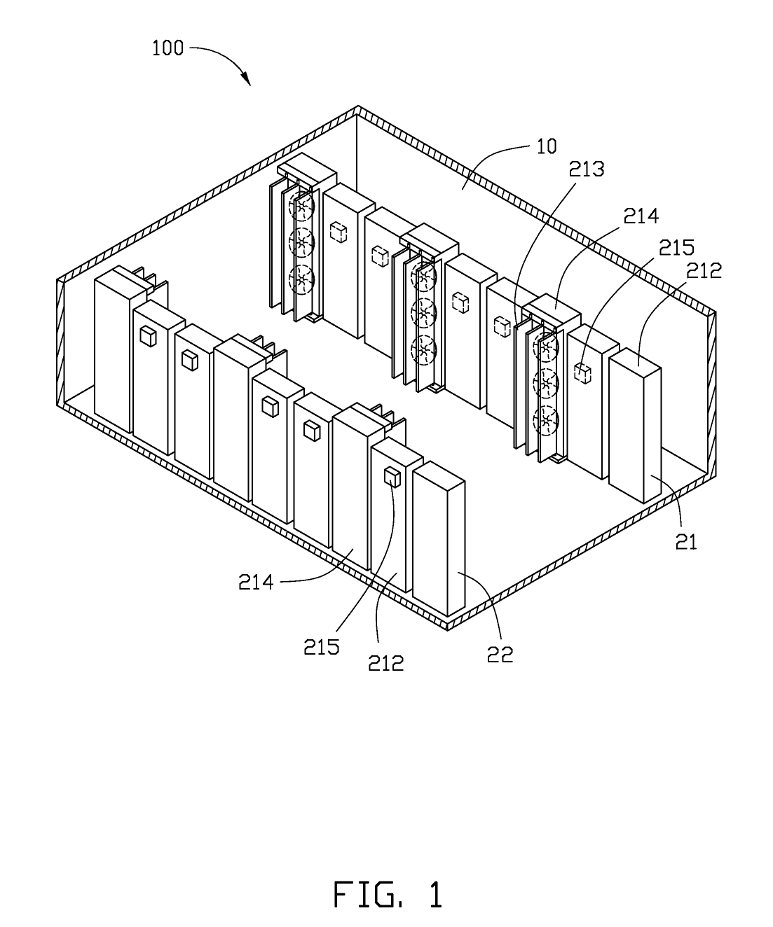

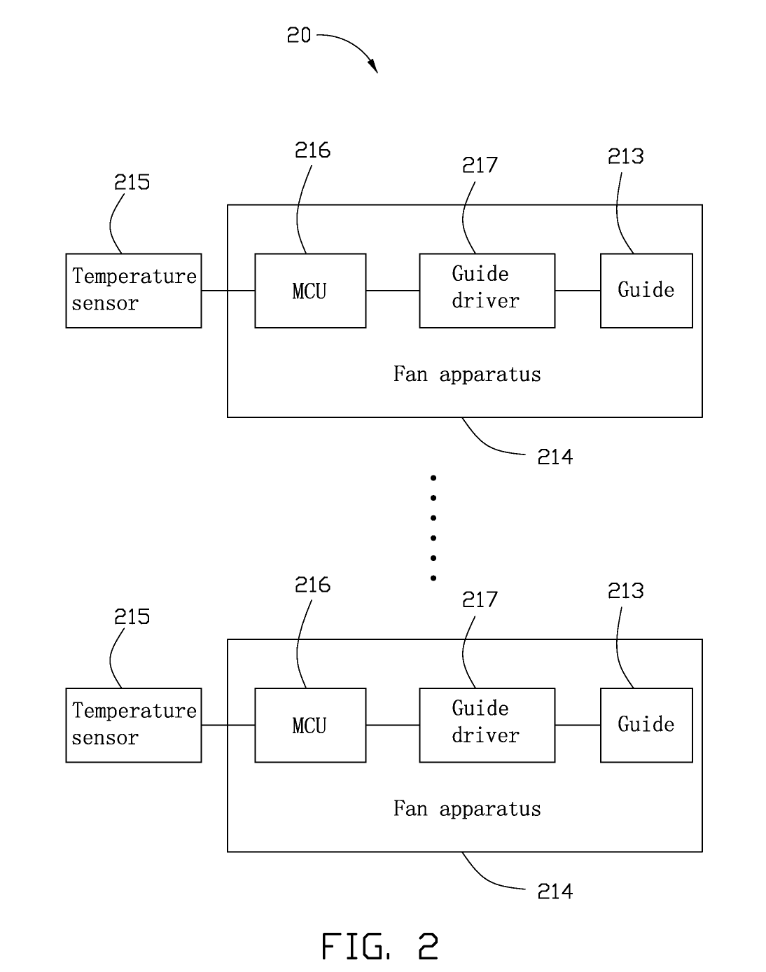

Referring to FIGS. 1 and 2, an embodiment of a container data center 100 includes a container 10, and a first row of server systems 21 and a second row of server systems 22. In one embodiment, the data center 100 is a container data center, the container 10 is movable, and the first row of server systems 21 and the second row of server systems 22 are installed in the container 10 in two parallel rows.

The first row of server systems 21 include a number of server systems 212 and a number of fan apparatuses 214. Each fan apparatus 214 is arranged between two adjacent server systems 212, and there are two adjacent server systems 212 arranged between every two adjacent fan apparatuses 214. The second row of server systems 22 has the same configuration as the first row of server systems 21 and is symmetrical with the first row of server systems 21 in the container 10. The number of the server systems 212 and the number of the fan apparatuses 214 can be adjusted according to the size of the container 10.

The fan apparatus 214 of one row of the first and second rows of server systems 21 and 22 generates cooling airflow to the other row of the first and second rows of server systems 21 and 22 to dissipate heat. Each fan apparatus 214 includes a number of guides 213 rotatably mounted on the front of the fan apparatus 214 to guide the airflow direction of the cooling airflow, a guide driver 217 to drive the guides 213, and a micro control unit (MCU) 216 to control the guide driver 217. Each server system 212 includes a temperature sensor 215 to determine the temperature of the server system 212. The MCU 216 of each fan apparatus 214 is connected to two temperature sensors 215 of two server systems 212 nearest to the fan apparatus 214 but not in the same row. All of the fan apparatuses 214 and temperature sensors 215 form a heat dissipation system 20 of the data center 100. The configuration of the guides 213 falls within well-known technologies, and is therefore not described here.

The following paragraphs describe only the working process of a fan apparatus 214 and the corresponding two temperature sensors 215. Since the other fan apparatuses 214 and temperature sensors 215 have the same working process, they are not described here.

In use, the two temperature sensors 215 determine temperature of two corresponding server systems 212. The MCU 216 of the fan apparatus 214 receives two temperature signals from the two temperature sensors 215 and compares the two temperature signals. If one temperature signal exceeds the other, the MCU 216 directs the guide driver 217 to rotate the guides 213 towards the server system 212 with higher temperature. If the two temperature signals are the same, the MCU 216 controls the guide driver 217 to rotate the guides 213 towards the center of the two server systems 212.

According to the above system, all of the fan apparatuses 214 in the data center 100 can provide cooling airflow in an appropriate angle through the guides 213, which can save electricity.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A container data center comprising:
a movable container; and
a first row of server systems and a second row of server systems installed in the container in two parallel rows, wherein each of the first row of server systems and the second row of server systems comprises a plurality of server systems and a plurality of fan apparatuses to provide cooling airflow to the other row of the first and second rows of server systems;
wherein each of the plurality of fan apparatuses comprises a plurality of guides rotatably mounted thereon to guide airflow of the cooling airflow, a guide driver to drive the plurality of guides, and a micro control unit (MCU) to control the guide driver;
wherein each of the plurality of server systems comprises a temperature sensor to determine temperature of the server system, wherein the MCU of each of the plurality of fan apparatuses is connected to two temperature sensors of two of the plurality of server systems nearest to the fan apparatus but not in the same row, the MCU of each of the plurality of fan apparatuses receives two temperature signals from two corresponding temperature sensors and directs the guide driver to rotate the plurality of guides towards the server system with highest temperature.

2. The container data center of claim 1, wherein the MCU of each of the plurality of fan apparatuses directs the guide driver to rotate the plurality of guides towards the center of the two server systems in response to the two temperature signals being the same.

3. The container data center of claim 1, wherein each of the plurality of fan apparatuses is arranged between two adjacent server systems of the plurality of server systems, and there are two adjacent server systems of the plurality of server systems arranged between every two adjacent fan apparatuses of the plurality of fan apparatuses, the second row of server systems has the same configuration and is symmetrical with the first row of server systems in the container.

4. A heat dissipation system for a server system assembly comprising a first row of server systems and a second row of server systems in two parallel rows, each of the first row of server systems and the second row of server systems comprising a plurality of server systems, the heat dissipation system comprising:
a plurality of fan apparatuses arranged in each of the first row of server systems and the second row of server systems, to provide cooling airflow to the opposite row of the first and second row of server systems; wherein each of the plurality of fan apparatuses comprises a plurality of guides rotatably mounted thereon to guide airflow of the cooling airflow, a guide driver to drive the plurality of guides, and a micro control unit (MCU) to control the guide driver; and
a plurality of temperature sensors arranged in the plurality of server systems to determine temperature of the corresponding server systems, wherein the MCU of each of the plurality of fan apparatuses is connected to two temperature sensors of two of the plurality of server systems nearest to the fan apparatus but not in the same row, the MCU of each of the plurality of fan apparatuses receives two temperature signals from two corresponding temperature sensors and controls the guide driver to drive the plurality of guides to rotate towards the one of the two of the plurality of server systems whose temperature is larger than the other one of the two of the plurality of server systems in response to one of the two temperature signals being larger than the other one of the two temperature signals.

5. The heat dissipation system of claim 4, wherein the MCU of each of the plurality of fan apparatus controls the guide driver to drive the plurality of guides to rotate towards the center of the two of the plurality of server systems in response to the two temperature signals being the same.

6. The heat dissipation system of claim 4, wherein each of the plurality of fan apparatuses is arranged between two adjacent server systems of the plurality of server systems, and there are two adjacent server systems of the plurality of server systems arranged between every two adjacent fan apparatuses of the plurality of fan apparatuses, the second row of server systems has the same configuration with the first row of server systems and is symmetrical with the first row of server systems.
